(19) United States
(12) Patent Application Publication
(10) Pub. No.: US 2004/0061222 A1
(43) Pub. Date: Apr. 1, 2004

(54) Window-type ball grid array semiconductor package

(76) Inventor: Jin-Chuan Bai, Hsin-Chu (TW)

Correspondence Address: FULBRIGHT AND JAWORSKI L L P, PATENT DOCKETING 29TH FLOOR, 865 SOUTH FIGUEROA STREET, LOS ANGELES, CA, 900172576

(21) Appl. No.: 10/261,835

(22) Filed: Sep. 30, 2002

(51) Int. Cl. H01L 23/48

(52) U.S. Cl. 257/734

(57) ABSTRACT

A window-type ball grid array (WBGA) semiconductor package is proposed, wherein a chip is mounted over an opening formed through a substrate via an adhesive in a manner as to leave regions adjacent to the opening on the substrate uncovered by the adhesive. A first encapsulant is formed to fill the opening and encapsulate bonding wires formed through the opening for electrically connecting the chip to the substrate. A second encapsulant is fabricated to encapsulate the chip. A non-conductive material is applied by a dispensing process to seal gaps formed between the chip and the regions on the substrate, so as to allow the chip to be firmly supported on the substrate during a molding process for fabricating the second encapsulant, and thus to prevent chip cracks from occurrence.

### FIELD OF THE INVENTION

The present invention relates to semiconductor packages, and more particularly, to a window-type ball grid array (WBGA) semiconductor package with a chip being mounted over an opening formed through a substrate and electrically connected to the substrate via the opening by bonding wires.

### BACKGROUND OF THE INVENTION

Window-type semiconductor packages are advanced packaging technology, characterized by forming at least an opening penetrating through a substrate, allowing a chip to be mounted over the opening, and electrically connected to the substrate by bonding wires through the opening. One benefit achieved by this window-type package structure is to shorten length of the bonding wires, thereby making electrical transmission or performances between the chip and the substrate more efficiently implemented.

A conventional window-type ball grid array (WBGA) semiconductor package 1 is exemplified with reference to FIGS. 5 and 6A-6C. As shown in FIGS. 5 and 6A, this WBGA semiconductor package 1 is composed of a substrate 10 formed with an opening 100 penetrating through the same; a chip 11 mounted over the opening 100 via an adhesive 12 on an upper surface 101 of the substrate 10 in a face-down manner that, an active surface 110 of the chip 11 faces toward the substrate 10 and is partly exposed to the opening 100; a plurality of bonding wires 13 formed through the opening 100 for electrically connecting the active surface 110 of the chip 11 to a lower surface 102 of the substrate 10; a first encapsulant 14 formed on the lower surface 102 of the substrate 10 for filling the opening 100 and encapsulating the bonding wires 13; a second encapsulant 15 formed on the upper surface 101 of the substrate 10 for encapsulating the chip 11; and a plurality of solder balls 16 implanted on the lower surface 102 of the substrate 10 and situated outside the first encapsulant 14.

The above conventional WBGA package 1 has significant drawbacks. As shown in FIGS. 5, 6B and 6C, however, between the chip 11 and the substrate 10 there may be formed gaps G corresponding in position to regions on the substrate 10 adjacent to the opening 100 and uncovered by the adhesive 12, for example, along two relatively shorter sides of the opening 100. During a molding process for fabricating the second encapsulant 15 on the substrate 10, the chip 11 at a position corresponding to the gaps G may lack for mechanical support from the substrate 10 and thus leads to chip-cracking in response to impact or force generated during molding, which would adversely affects reliability and yield of fabricated package products.

Therefore, the problem to be solved herein is to provide a semiconductor package for allowing a chip to be well supported on a substrate during a molding process for encapsulating the chip, so as to prevent chip cracks from occurrence.

### SUMMARY OF THE INVENTION

A primary objective of the present invention is to provide a window-type ball grid array (WBGA) semiconductor package, which allows a chip to be firmly supported on a substrate so as to prevent chip cracks during a molding process for encapsulating the chip, thereby assuring reliability and yield of fabricated package products.

In accordance with the above and other objectives, the present invention proposes a WBGA semiconductor package, comprising: a substrate having an upper surface and a lower surface opposed to the upper surface, and formed with at least an opening penetrating through the upper and lower surfaces; at least a chip having an active surface and a non-active surface opposed to the active surface, wherein the chip is mounted over the opening via an adhesive on the upper surface of the substrate in a manner as to partly expose the active surface of the chip to the opening, and to leave regions adjacent to the opening on the upper surface of the substrate uncovered by the adhesive; a nonconductive material applied on the upper surface of the substrate to seal gaps formed between the chip and the regions on the substrate; a plurality of bonding wires formed through the opening for electrically connecting the exposed part of the active surface of the chip to the lower surface of the substrate; a first encapsulant formed on the lower surface of the substrate for filling the opening and encapsulating the bonding wires; a second encapsulant formed on the upper surface of the substrate for encapsulating the chip; and a plurality of solder balls implanted on the lower surface of the substrate and situated outside the first encapsulant.

The above package structure provides significant benefits. With the gaps between the chip and the substrate being sealed by the non-conductive material, the chip can be enhanced in mechanical support at a position corresponding to the regions uncovered by the adhesive on the substrate. During a molding process for fabricating the second encapsulant that encapsulates the chip, the non-conductive material formed on the upper surface of the substrate in accompany with the first encapsulant formed on the lower surface of the substrate, can provide firm support to the chip mounted on the substrate, so as to prevent chip-cracking that occurs in the prior art due to lack of gap-sealing between a chip and a substrate; thereby, the provision of the gap-sealing non-conductive material in this invention can desirably assuring reliability and yield of fabricated package products.

### BRIEF DESCRIPTION OF THE DRAWINGS

The present invention can be more fully understood by reading the following detailed description of the preferred embodiments, with reference made to the accompanying drawings, wherein:

FIG. 1 is a top view of a semiconductor package according to a preferred embodiment of the invention;

FIGS. 2A, 2B and 2C are cross-sectional views of the semiconductor package shown in FIG. 1 respectively taken along lines 2A-2A, 2B-2B and 2C-2C;

FIG. 3 is a cross-sectional view of the semiconductor package according to another preferred embodiment of the invention;

FIG. 4A is a top view of the semiconductor package according to a further preferred embodiment of the invention;

FIG. 4B is a cross-sectional view of the semiconductor package shown in FIG. 4A taken along a line 4B-4B.

FIG. 5 (PRIOR ART) is a top view of a conventional semiconductor package; and

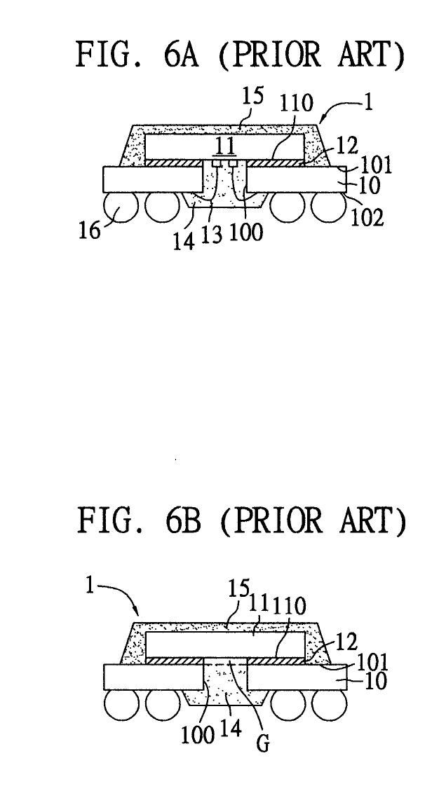

FIGS. 6A, 6B and 6C (PRIOR ART) are cross-sectional views of the semiconductor package shown in FIG. 5 respectively taken along lines 6A-6A, 6B-6B and 6C-6C.

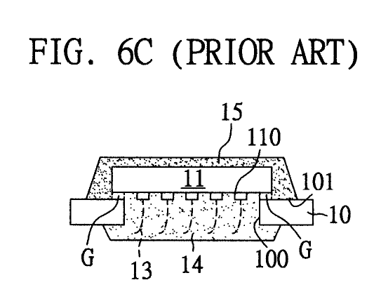

### DETAILED DESCRIPTION OF THE PREFERRED EMBODIMENTS

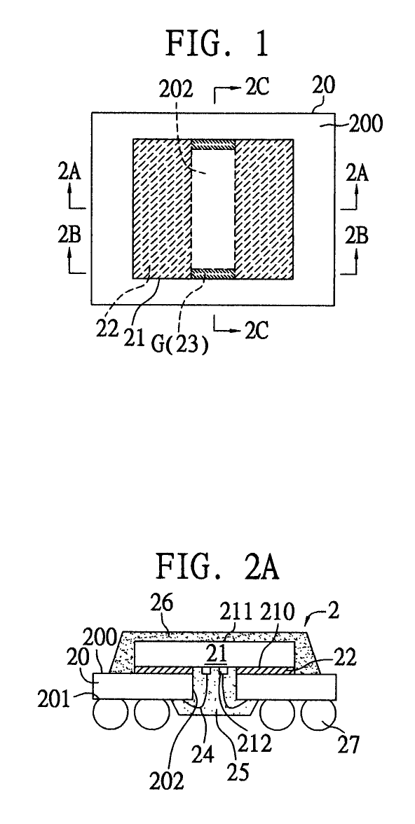

Preferred embodiments for a window-type ball grid array (WBGA) semiconductor package proposed in the present invention are described in more detail as follows with reference to FIGS. 1, 2A-2C, 3 and 4A-4B.

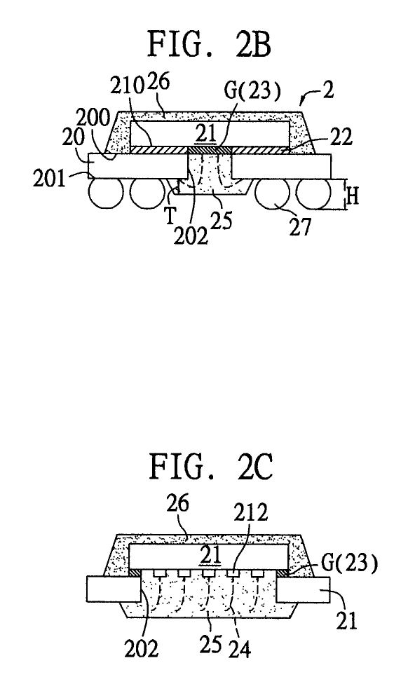

FIGS. 1 and 2A-2C illustrate a WBGA semiconductor package 2 according to a preferred embodiment of the invention. As shown in the drawings, the WBGA semiconductor package 2 is a substrate-based structure with a substrate 20 having an upper surface 200 and a lower surface 201 opposed to the upper surface 200, wherein an opening 202 is formed to penetrate through the upper and lower surfaces 200, 201 of the substrate 20. The substrate 20 is primarily made of a conventional resin material such as epoxy resin, polyimide, BT resin, FR-4 resin, etc.

A chip 21 has an active surface 210 where electronic elements and circuits are formed, and a non-active surface 211 opposed to the active surface 210. The chip 21 is mounted over the opening 202 via an adhesive 22 on the upper surface 200 of the substrate 20 in a face-down manner that, the active surface 210 of the chip 21 faces toward the substrate 20 and is partly exposed to the opening 202, so as to allow a plurality of bond pads 212 formed on the active surface 210 of the chip 21 to be exposed via the opening 202 of the substrate 20 and subject to a subsequent wire-bonding process. However, on the upper surface 200 of the substrate 20 there are left regions adjacent to the opening 202 and uncovered by the adhesive 22, for example, along relatively shorter sides of the opening 202 (as shown in FIG. 1); the opening 202 may be substantially shaped as (but not limited to) a rectangle with two longer sides and two shorter sides. As a result, gaps G are formed between the active surface 210 of the chip 21 and the substrate 20 corresponding in position to the adhesive-uncovered regions on the substrate 20. As illustrated in FIG. 2A, the bond pads 212 are situated substantially at (but not limited to) central area on the active surface 210 of the chip 21; such a chip 21 with the centrally-situated bond pads 212 may be a DRAM (dynamic random access memory) chip.

A non-conductive material 23 is applied by a dispensing process to seal the gaps G between the chip 21 and the substrate 20 along the shorter sides of the opening 202 It should be understood that, applying of the non-conductive material 23 is not limited to the dispensing technology.

A plurality of bonding wires 24 e.g. gold wires are formed through the opening 202 and bonded to the exposed bond pads 212 formed on the chip 21, so as to electrically connect the active surface 210 of the chip 21 to the lower surface 201 of the substrate 20 by means of the bonding wires 24.

A first encapsulant 25 is formed by a printing process on the lower surface 201 of the substrate 20 for filling the opening 202 and encapsulating the bonding wires 24. As shown in FIG. 2C, the non-conductive material 23 for sealing the gaps G between the chip 21 and the substrate 20, is situated substantially corresponding in position to peripheral part of the first encapsulant 25. The non-conductive material 23 may be the same as or different from a material for making the first encapsulant 25.

A second encapsulant 26 is formed by a molding process on the upper surface 200 of the substrate 20 for encapsulating the chip 21. The second encapsulant 26 may be made of a resin material different from that for fabricating the first encapsulant 25.

A plurality of solder balls 27 are implanted on the lower surface 201 of the substrate 20 and situated outside the first encapsulant 25. And, height H of the solder balls 27 is greater than thickness T of the first encapsulant 25 protruding from the lower surface 201 of the substrate 20. The solder balls 27 serve as I/O (input/output) ports of the semiconductor package 2 for electrically connecting the chip 21 to an external device such as a printed circuit board (PCB).

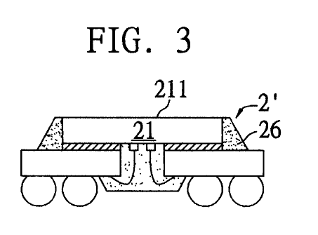

FIG. 3 illustrates a semiconductor package 2′ according to another preferred embodiment of the invention. As shown in the drawing, this semiconductor package 2′ structurally differs from the above semiconductor package 2 in that, the non-active surface 211 of the chip 21 in this semiconductor package 2′ is exposed to outside of the second encapsulant 26 that encapsulates the chip 21. This structural arrangement facilitates dissipation of heat generated from operation of the chip 21 via the exposed non-active surface 211 of the chip 21.

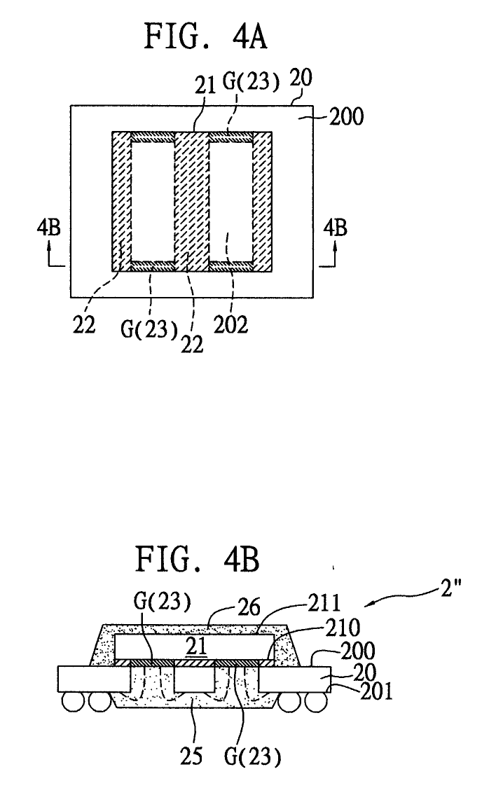

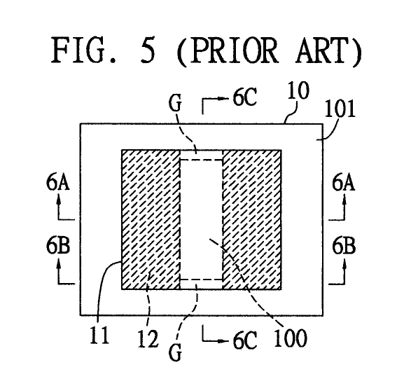

FIGS. 4A and 4B illustrate a semiconductor package 2″ according to a further preferred embodiment of the invention. As shown in the drawings, this semiconductor package 2″ structurally differs from the above semiconductor package 2 in that, a plurality of openings 202 are formed through the substrate 20, for allowing peripherally-situated bond pads (not shown) of the chip 21 to be exposed via the openings 202 for electrical connection and wire-bonding purposes, such that chips peripherally formed with bond pads can also be adopted herein. In the semiconductor package 2″, gaps G similarly corresponding in position to regions on the upper surface 200 of the substrate 20 adjacent to the openings 202 and uncovered by the adhesive 22 that attaches the chip 21 to the substrate 20, are formed between the chip 21 and the substrate 20 and desirably sealed by the non-conductive material 23.

The above package structure provides significant benefits. With the gaps G between the chip 21 and the substrate 20 being sealed by the non-conductive material 23, the chip 21 can be enhanced in mechanical support at a position corresponding to the regions uncovered by the adhesive 22 on the substrate 20. During the molding process for fabricating the second encapsulant 26 that encapsulates the chip 21, the non-conductive material 23 formed on the upper surface 200 of the substrate 20 in accompany with the first encapsulant 25 formed on the lower surface 201 of the substrate 20, can provide firm support to the chip 21 mounted on the substrate 20, so as to prevent chip-cracking that occurs in the prior art due to lack of gap-sealing between a chip and a substrate; thereby, the provision of the gap-sealing non-conductive material 23 in this invention can desirably assuring reliability and yield of fabricated package products.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A window-type ball grid array semiconductor package, comprising:
a substrate having an upper surface and a lower surface opposed to the upper surface, and formed with at least an opening penetrating through the upper and lower surfaces,
at least a chip having an active surface and a non-active surface opposed to the active surface, wherein the chip is mounted over the opening via an adhesive on the upper surface of the substrate in a manner as to expose at least a conductive area on the active surface of the chip to the opening, and to leave regions adjacent to the opening on the upper surface of the substrate uncovered by the adhesive,
a non-conductive material applied on the upper surface of the substrate to seal gaps formed between the chip and the regions on the substrate;
a plurality of bonding wires formed through the opening for electrically connecting the conductive area of the chip to the lower surface of the substrate;
a first encapsulant formed on the lower surface of the substrate for filling the opening and encapsulating the bonding wires;
a second encapsulant formed on the upper surface of the substrate for encapsulating the chip; and
a plurality of solder balls implanted on the lower surface of the substrate and situated outside the first encapsulant;
wherein with the gaps between the chip and the substrate being sealed by the non-conductive material, the chip is firmly supported on the substrate when the second encapsulant is formed for encapsulating the chip, so as to prevent chip cracks from occurrence.

2. The semiconductor package of claim 1, wherein the chip is formed with a plurality of bond pads on the conductive area of the active surface thereof allowing the bond pads to be exposed to the opening of the substrate.

3. The semiconductor package of claim 2, wherein the bonding wires are bonded to the exposed bond pads of the chip.

4. The semiconductor package of claim 1, wherein the chip is dimensioned to completely cover the opening of the substrate.

5. The semiconductor package of claim 1, wherein the non-conductive material is applied in a dispensing manner.

6. The semiconductor package of claim 1, wherein the first encapsulant is formed in a printing manner.

7. The semiconductor package of claim 1, wherein the second encapsulant is formed in a molding manner.

8. The semiconductor package of claim 1, wherein the first and second encapsulants are made of different materials.

9. The semiconductor package of claim 1, wherein the non-conductive material is the same as a material for making the first encapsulant.

10. The semiconductor package of claim 1, wherein the non-conductive material is different from a material for making the first encapsulant.

11 The semiconductor package of claim 1, wherein the non-active surface of the chip is exposed to outside of the second encapsulant.

12. The semiconductor package of claim 1, wherein height of the solder balls is greater than thickness of the first encapsulant protruding from the lower surface of the substrate.
